(19) United States
(12) Patent Application Publication
(10) Pub. No.: US 2026/0037371 A1
(43) Pub. Date: Feb. 5, 2026

(54) MEMORY SYSTEM, MEMORY DEVICE AND OPERATING METHODS THEREOF

(71) Applicant: SK hynix Inc., Icheon-si (KR)

(72) Inventors: Yong Jun LEE, San Jose, CA (US); Hoiju CHUNG, San Jose, CA (US); Woong Ju JANG, San Jose, CA (US); Eui Sang OH, San Jose, CA (US)

(21) Appl. No.: 18/928,042

(22) Filed: Oct. 27, 2024

Related U.S. Application Data
(60) Provisional application No. 63/678,275, filed on Aug. 1, 2024.

(51) Int. Cl. G06F 11/10

(52) U.S. Cl. CPC G06F 11/1044

(57) ABSTRACT

A memory system includes a plurality of memory devices each including a memory cell region and an error correction circuit; and a memory controller configured to independently provide an off mode signal and an off address to the plurality of memory devices, wherein, during a read operation, each of the plurality of memory devices controls the error correction circuit to selectively perform an error correction operation on an exclusion area in the memory cell region defined by the off address, according to the off mode signal.

### CROSS-REFERENCE TO RELATED APPLICATION

The patent application claims the benefit of priority under 35 U.S.C. § 119 (e) to U.S. Provisional Application No. 63/678,275 filed on Aug. 1, 2024, which is incorporated herein by reference in its entirety.

### BACKGROUND

### 1. Field

Various embodiments of the present disclosure relate to a semiconductor design technology, and more particularly, to a memory system including a memory device employing an on-chip ECC scheme.

### 2. Description of the Related Art

In the early days of the semiconductor memory industry, there were many original good dies with no defective memory cells, in a memory chip that has passed a semiconductor fabrication process on the wafer. However, as the capacity of memory devices gradually increase, it became difficult to make a memory device completely free of a defective memory cell, and at present, it may be said that there is likely no possibility that a memory device with no defective memory cell is fabricated. As one solution to overcome this situation, a method of repairing defective memory cells of a memory device with redundant memory cells or a method of correcting an error in data of memory cells using an error correction circuit is being used.

Meanwhile, in a memory device employing an on-chip ECC scheme, when an error correction circuit with a single-bit error correction capability corrects a multi-bit error, miscorrection of the error correction circuit occurs. As a result, the number of error bits further increases, and error bits that could have been sufficiently covered by an error correction capability of a memory controller (or a host) cannot be corrected. Recently, various methods have been discussed to manage such a miscorrection so that the miscorrection occurs within a boundary of preset specifications.

### SUMMARY

Embodiments of the present disclosure are directed to a memory system including a plurality of memory devices, the memory system capable of independently designating an exclusion area where an error beyond an error correction capability may occur, for each memory device, and selectively performing an error correction operation on data read from the exclusion area of each memory device during a read operation.

According to an embodiment of the present disclosure, a memory system includes a plurality of memory devices each including a memory cell region and an error correction circuit; and a memory controller configured to independently provide an off mode signal and an off address to the plurality of memory devices, wherein, during a read operation, each of the plurality of memory devices controls the error correction circuit to selectively perform an error correction operation on an exclusion area in the memory cell region defined by the off address, according to the off mode signal.

According to an embodiment of the present disclosure, a memory device includes a memory cell region; an error correction circuit configured to selectively perform an error correction operation on data read from a target area in the memory cell region according to a correction off signal, during a read operation; a mode setting circuit configured to store a preliminary off mode signal and an off address according to a mode setting command; and an error correction control circuit configured to generate the correction off signal by checking whether the target area is included in an exclusion area defined by the off address according to an off command or the preliminary off mode signal.

According to an embodiment of the present disclosure, an operating method of a memory device includes storing a preliminary off mode signal and an off address in a mode setting circuit according to a mode setting command; generating an off mode signal according to an off command or the stored preliminary off mode signal; receiving a read command for a target area in a memory cell region; checking whether the target area is included in an exclusion area defined by the off address according to the off mode signal; and selectively performing an error correction operation on data read from the target area according to the checking result.

According to an embodiment of the present disclosure, an operating method of a memory system includes providing, at a memory controller, an off mode signal and an off address defining an exclusion area to at least one selected memory device among a plurality of memory devices; storing the off mode signal and the off address, at the selected memory device; providing, at the memory controller, a read command for a target area to the plurality of memory devices; checking, at the selected memory device, whether the target area is included in the exclusion area according to the off mode signal and the off address; and selectively performing, at the selected memory device, an error correction operation on data read from the target area according to the checking result.

According to embodiments of the present disclosure, the memory device may prevent an uncorrectable error (UE) that may occur due to the miscorrection of the error correction circuit by omitting the error correction operation on data read from the exclusion area where an error may occur in the memory cell region.

Further, according to embodiments of the present disclosure, the memory system may omit/skip the error correction operation on the exclusion area, which is independently designated for each memory device, to thereby correct a single-bit error covered by the error correction capability, by using an internal error correction operation thereof, and correct a multi-bit error beyond the error correction capability, by using an external error correction operation of a memory controller. Accordingly, the memory system may maximize the error correction capability and provide an optimized RAS (Reliability, Accessibility, and Serviceability) operation.

### BRIEF DESCRIPTION OF THE DRAWINGS

FIG. 1 is a block diagram illustrating a memory system according to an embodiment of the present disclosure.

FIG. 2 is a diagram for explaining data input/output of a memory device of FIG. 1 according to an embodiment of the present disclosure.

FIG. 3 is a diagram illustrating a miscorrection that may occur during a read operation of FIG. 2 according to an embodiment of the present disclosure.

FIG. 4 is a detailed block diagram illustrating a memory device in FIG. 1 according to an embodiment of the present disclosure.

FIG. 5 is a diagram illustrating an exclusion area defined by an off address of FIG. 4 according to an embodiment of the present disclosure.

FIG. 6 is a detailed block diagram illustrating an error correction control circuit of FIG. 4 according to an embodiment of the present disclosure.

FIGS. 7 and 8 are flowcharts for describing an operation of a memory device according to an embodiment of the present disclosure.

FIG. 9 is a flowchart for explaining an operation of a memory system according to an embodiment of the present disclosure.

FIGS. 10A to 10C are diagrams illustrating operations of a memory system according to an embodiment of the present disclosure.

### DETAILED DESCRIPTION

Various embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “connected” to another element, it may mean that the two are directly coupled or the two are electrically connected to each other with another circuit or element intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

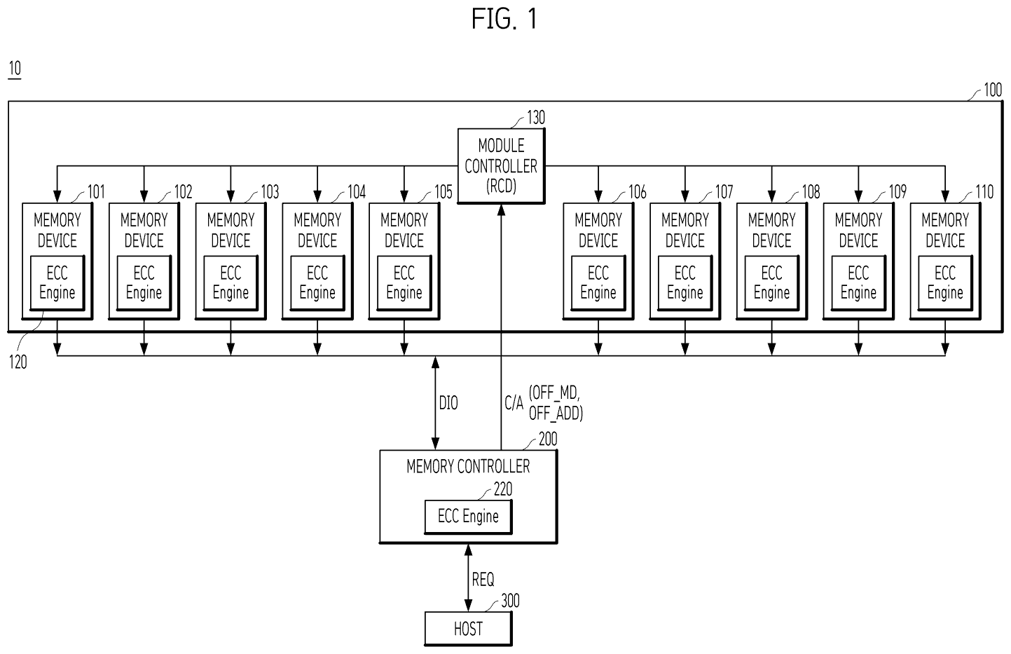

FIG. 1 is a block diagram illustrating a memory system according to an embodiment of the present disclosure.

Referring to FIG. 1, a memory system 10 may include a memory module 100 and a memory controller 200.

The memory module 100 may include a plurality of memory devices 101 to 110 and a module controller RCD 130. The module controller 130 may include a known register clock driver. The module controller 130 may control the memory devices 101 to 110 under the control of the memory controller 200. For example, the module controller 130 may receive a command/address signal C/A from the memory controller 200 to control data DIO to be written to or read from the memory devices 101 to 110.

The plurality of memory devices 101 to 110 may be referred to as a plurality of memory chips. Each of the plurality of memory devices 101 to 110 may store the data DIO. The plurality of memory devices 101 to 110 are separated from each other and may transmit and receive the data DIO to and from the memory controller 200 through a separate data bus, and may receive the command/address signal C/A from the module controller 130 through a shared command/address bus. Each of the memory devices 101 to 110 may include a memory cell array (hereinafter, referred to as a memory cell region) including a plurality of memory cells storing the data DIO. Each of the memory devices 101 to 110 may include a dynamic random access (DRAM) including dynamic memory cells. In an embodiment, each of the memory devices 101 to 110 may include double data date (DDR) synchronous DRAM (SDRAM), low-power DDR type SDRAM, graphics DDR (GDDR) SDRAM, Rambus DRAM (RDRAM), and so on.

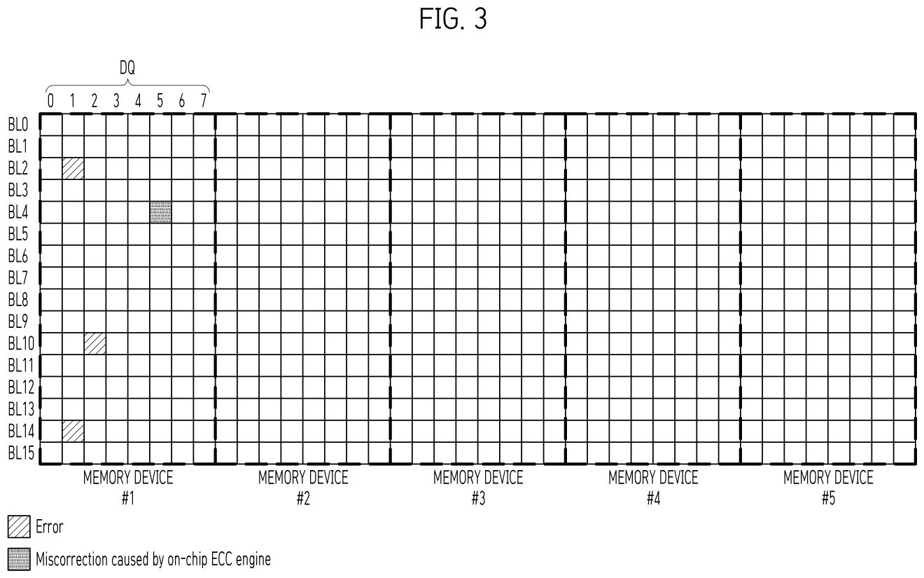

In an embodiment of the present invention, each of the memory devices 101 to 110 may include an ECC engine 120. The ECC engine 120 may be referred to as an on-chip ECC engine. The ECC engine 120 may correct an error in the data DIO output from the memory cell region and output error-corrected data to the memory controller 200. Meanwhile, when error bits beyond an error correction capability of the ECC engine 120 occur, a miscorrection may occur. The miscorrection will be described below with reference to FIG. 3.

The memory controller 200 may control the overall operation of the memory system 10 and control a data exchange between a host 300 and the memory module 100. The memory controller 200 may generate the command/address signal C/A in response to a request REQ from the host 300 to provide the command/address signal C/A to the memory module 100. The memory controller 200 may provide the data DIO corresponding to the request REQ provided from the host 300 to the memory module 100, and transmit the data DIO read from the memory module 100 to the host 300. For example, the memory controller 200 may provide a write command, an address, and data to the memory module 100 during a write operation, and the memory devices 101 to 110 of the memory module 100 may write the data DIO to an area selected by the address according to the write command. Further, the memory controller 200 may provide a read command and address to the memory module 100 during a read operation, the memory devices 101 to 110 may read data DIO from an area selected by the address according to the read command, and the memory controller 200 may provide data read from the memory devices 101 to 110 to the host 300.

The memory controller 200 may include an ECC engine 220. The error correction capability of each of the memory devices 101 to 110 may be set to be smaller than an error correction capability of the memory controller 200. That is, the ECC engine 220 of the memory controller 200 may have an error correction capability greater than the ECC engine 120 in each of the memory devices 101 to 110. For example, the ECC engine 120 may correct only single-bit errors, but the ECC engine 220 may correct multi-bit errors.

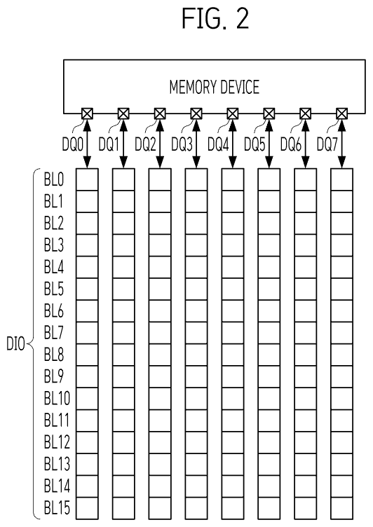

FIG. 2 is a diagram for explaining data input/output of a memory device of FIG. 1 according to an embodiment of the present disclosure. For example, the data input/output of a memory device 101 is shown in FIG. 2.

Referring to FIG. 2, the memory device 101 may use a number of data pads (i.e., first to eighth data pads DQ0 to DQ7) corresponding to a data bus width to input/output the data DIO according to a preset data width option (e.g., 8-bit). In addition, the memory device 101 may perform a burst operation for converting data outputted from the memory cell region in parallel into a serial order, and outputting the converted data during a preset burst length (e.g., 16).

Accordingly, the memory device 101 of FIG. 2 may input/output the data DIO of 8*16=128 bits in a single read operation or write operation by inputting/outputting the data DIO through the first to eighth data pads DQ0 to DQ7 during a burst length BL0 to BL15. That is, since each memory device inputs and outputs 128 bits (i.e., 16 bytes) of data, the memory module 100 of FIG. 1 may input and output 160 bytes of data to and from the memory controller 200 during a single read operation or write operation.

The memory device 101 of FIG. 2 exemplarily illustrates a data width option set to 8 and a burst length is set to 16, but proposed embodiments are not limited thereto. Various bit numbers of data may be input and output according to the settings of the data width option and the burst length.

FIG. 3 is a diagram illustrating a miscorrection that may occur during a read operation of FIG. 2 according to an embodiment of the present disclosure.

During the read operation, the ECC engine 120 of the memory device 101 may correct a single-bit error covered by its own error correction capability, but output a multi-bit error to the memory controller 200 without correcting the multi-bit error. When an error exceeding the error correction capability occurs, a malfunction may take place in which the ECC engine 120 performs an error correction operation on normal data in which no error has occurred, that is a miscorrection. Due to such a miscorrection, the number of error bits included in an error in data output from the memory devices may increase.

For example, referring to FIG. 3, each memory device of first to fifth memory devices #1 to #5 outputs 128 bits of data through the first to eighth data pads DQ0 to DQ7 during the burst lengths BL0 to BL15. When a 3-bit error occurs in data output through the second data pad DQ1 and the third data pad DQ2 of the first memory device #1, normal data output through the sixth data pad DQ5 may be miscorrected due to the malfunction of the ECC engine 120, i.e., an on-chip ECC engine.

If a multi-bit error exceeding the error correction capability of the on-chip ECC engine occurs, however, it may be covered by the error correction capability of the memory controller 200. For example, when the memory controller 200 is set to have an error correction capability to cover an error in data output from two adjacent data pads, the 3-bit error of data output through the second data pad DQ1 and the third data pad DQ2 of the first memory device #1 may be corrected. However, an error in data output through the sixth data pad DQ5 caused by the miscorrection of the on-chip ECC engine becomes uncorrectable, and the possibility of an uncorrectable error (UE) increases.

Referring back to FIG. 1, in an embodiment of the present disclosure, the memory controller 200 may independently provide an off mode signal OFF_MD and an off address OFF_ADD to the plurality of memory devices 101 to 110. The off mode signal OFF_MD and the off address OFF_ADD may be provided in the form of the command/address signal C/A. Each of the memory devices 101 to 110 may control its ECC engine 120 to selectively perform an error correction operation on an area (hereinafter, referred to as an “exclusion area”) defined by the off address OFF_ADD, in the memory cell region according to the off mode signal OFF_MD, during a read operation.

The memory controller 200 may generate information on an area in which errors beyond the error correction capability of each memory device 101 to 110 may occur. Hereinafter, the exclusion area may be defined as an area in which an error (i.e., a multi-bit error) beyond the error correction capability of the corresponding memory device occurs, an area in which an uncorrectable error UE occurs, or an area in which a miscorrection occurs. For example, the ECC engine 220 of the memory controller 200 may collect an address of an area in which a multi-bit error has occurred from each of the memory devices 101 to 110, based on the data DIO. The memory controller 200 may independently generate an off mode signal OFF_MD and an off address OFF_ADD for each of the memory devices 101 to 110 based on the collected addresses. For example, when an address of an area in which a multi-bit error has occurred is collected from the memory device 101, the memory controller 200 may activate an off mode signal OFF_MD for the memory device 101 and generate an off address OFF_ADD corresponding to the collected address. Meanwhile, if no address of an area where a multi-bit error has occurred is collected from the memory device 102, the memory controller 200 may deactivate the off mode signal OFF_MD for the memory device 102.

Depending on an embodiment, the memory controller 200 may independently provide an off mode signal OFF_MD and an off address OFF_ADD to each of the memory devices 101 to 110 together with a mode setting command. Each of the memory devices 101 to 110 may store the off mode signal OFF_MD and the off address OFF_ADD in an internal mode setting circuit according to a mode setting command. The mode setting circuit may include a known mode register set.

Depending on an embodiment, even if an address of an exclusion area of a specific memory device is collected, the memory controller 200 may generate only an off address OFF_ADD corresponding to the collected address, while deactivating an off mode signal OFF_MD for the corresponding memory device. The memory controller 200 may independently provide the off address OFF_ADD to each of the memory devices 101 to 110 using a mode setting command. Thereafter, the memory controller 200 may additionally provide an off command on the fly between operations of each of the memory devices 101 to 110, and each of the memory devices 101 to 110 may activate an off mode signal OFF_MD according to the off command.

In a memory module that is separated from a data bus, but shares a command/address bus, a per-DRAM addressability (PDA) mode may be supported to perform an independent mode register setting operation for each of the memory devices 101 to 110. When a mode setting command from among the command/address signal C/A is inputted, each of the memory devices 101 to 110 may determine an entry to the PDA mode according to a specific bit of data DIO transmitted from the memory controller 200, and receive a command/address signal C/A transmitted in the PDA mode. That is, each of the memory devices 101 to 110 may independently store the off mode signal OFF_MD and the off address OFF_ADD provided in the PDA mode in an internal mode setting circuit.

As described above, in an embodiment of the present disclosure, the memory controller 200 may independently set an exclusion area of each of the memory devices 101 to 110. During a read operation, a memory device with a target area in which data are to be read and is included in the exclusion area may omit the error correction operation on the read data from the target area, and output the read data for which an error has not been corrected to the memory controller 200. The remaining memory devices with target areas not included in the exclusion area may perform an error correction operation on read data from the target area, and output error-corrected data to the memory controller 200. As a result, the memory controller 200 may correct a multi-bit error of read data provided from all the memory devices 101 to 110. Accordingly, the memory system may prevent the occurrence of an uncorrectable error (UE) due to the miscorrection of the on-chip ECC engine by managing the error within a boundary for a fault coverage.

Hereinafter, a configuration of each memory device according to an embodiment of the present disclosure will be described with reference to drawings. Since the memory devices 101 to 110 have substantially the same configuration, a configuration of the memory device 101 will be described as an example.

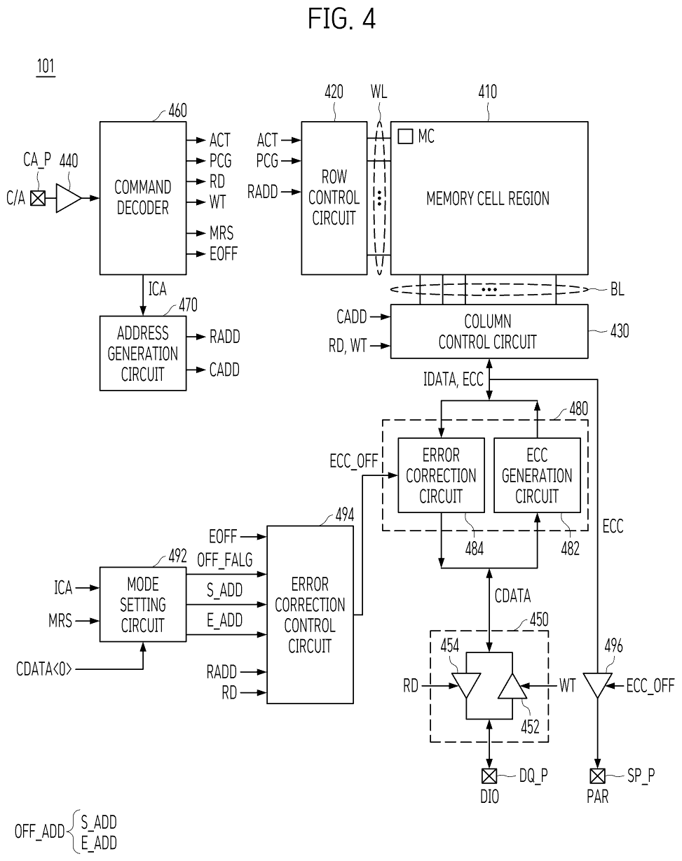

FIG. 4 is a detailed block diagram illustrating a memory device in FIG. 1 according to an embodiment of the present disclosure.

Referring to FIG. 4, a memory device 101 may include a memory cell region 410, a row control circuit 420, a column control circuit 430, a command/address (CA) receiving circuit 440, a data input/output circuit 450, a command decoder 460, an address generation circuit 470, an error correction code (ECC) engine 480, a mode setting circuit 492, and an error correction control circuit 494. The ECC engine 480 may correspond to an ECC engine 120 of FIG. 1.

The memory cell region 410 may include a plurality of memory cells MC disposed in an array type. The plurality of memory cells MC may be coupled to the row control circuit 420 through a plurality of word lines WL and coupled to the column control circuit 430 through a plurality of bit lines BL. The plurality of word lines WL may extend in a first direction (e.g., a row direction) and may be sequentially disposed in a second direction (e.g., a column direction) perpendicular to the first direction. The plurality of bit lines BL may extend in the column direction and may be sequentially disposed in the row direction. The plurality of memory cells MC may be composed of memory cells that require a refresh operation to secure data retention time. The memory cell region 410 may be composed of at least one bank. The number of banks or the number of memory cells MC may be determined depending on the capacity of the memory device 101.

The memory cell region 410 may include a plurality of cell blocks arranged in the row direction and the column direction. Each cell block may include the plurality of memory cells MC connected between the plurality of word lines WL and the plurality of bit lines BL. The plurality of cell blocks may include a plurality of normal cell blocks and at least one ECC cell block. The plurality of normal cell blocks may store data IDATA transmitted from the data input/output circuit 450, and the ECC cell block may store an error correction code ECC generated from the error correction circuit 484.

The row control circuit 420 may perform an active operation of activating a word line selected by a row address RADD according to an active command ACT, and a precharge operation of precharging the active word line according to a precharge command PCG.

The column control circuit 430 may select some of the bit lines BL of the memory cell region 410 according to a column address CADD, perform a read operation of reading the data IDATA and the error correction code ECC from the memory cells MC through the selected bit lines according to a read command RD, and perform a write operation of writing the data IDATA and the error correction code ECC to the memory cells MC through the selected bit lines according to a write command WT.

The CA receiving circuit 440 may receive a command/address signal C/A input through a command/address pad CA_P. Depending on the type of memory device 101, a command and an address may be input through the same input terminals, or a command and an address may be input through separate input terminals. In FIG. 3, it is illustrated that the command and the address are input through the same input terminals. The command/address signal C/A may be formed of multiple bits.

The data input/output circuit 450 may transmit or receive data DIO through a data pad DQ_P. The data input/output circuit 450 may include a data input circuit 452 and a data output circuit 454. The data input circuit 452 may receive the data DIO to be written to the memory cell region 410 in response to the write command WT. The data output circuit 545 may output the data DIO read from the memory cell region 410 in response to the read command RD.

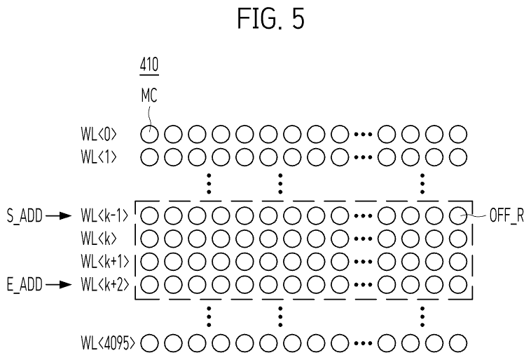

The command decoder 460 may decode the command/address signal C/A received by the CA receiving circuit 440 to generate the active command ACT, the precharge command PCG, the write command WT, the read command RD, a mode setting circuit MRS, and an off command EOFF. The active command ACT is a signal input when an active operation is instructed, the precharge command PCG is a signal input when a precharge operation is instructed, the write command WT is a signal input when a write operation is instructed, and the read command RD may be a signal input when a read operation is instructed. In addition, the mode setting command MRS is a command for storing and reading data in the mode setting circuit 492, and may include a mode register write command MRW for storing and reading data stored in the mode setting circuit 492 and a mode register read command MRR for reading data stored in the mode setting circuit 492 to the outside. Hereinafter, described in an embodiment of the present disclosure, the mode setting command MRS may include a mode register write command MRW. The off command EOFF may be a command for setting (or activating) an off mode signal (OFF_MD in FIG. 5), which will be described later.

The address generation circuit 470 may classify an internal address ICA received from the command decoder 460 into the row address RADD and the column address CADD. The row address RADD may be an address for selecting one of the plurality of word lines WL, and the column address CADD may be an address for selecting bit lines for performing the read operation from the plurality of bit lines BL. Each of the row address RADD and the column address CADD may be formed of multiple bits.

The ECC engine may include an ECC generation circuit 482 and an error correction circuit 484.

The ECC generation circuit 482 may generate the error correction code ECC by using data CDATA input through the data input circuit 452 during the write operation. During the write operation, since the error correction code ECC is generated using the data CDATA and an error of the data CDATA is not corrected, the data CDATA input to the ECC generation circuit 482 are identical to the data IDATA output from the ECC generation circuit 482.

The error correction circuit 484 may output error-corrected data CDATA by correcting an error of the data IDATA using the error correction code ECC in response to a correction off signal ECC_OFF, during the read operation. Here, the data IDATA and the error correction code ECC may be read from the memory cell region 410, during the read operation. The error correction circuit 484 may generate an error location signal indicating a bit (hereinafter, referred to as an error bit) where an error is located among bits of the data IDATA, based on the error correction code ECC, and may perform an error correction operation of inverting the error bit of the data IDATA according to the error location signal. Meanwhile, in an embodiment of the present invention, the error correction circuit 484 may selectively perform an error correction operation according to the correction off signal ECC_OFF. For example, the error correction circuit 484 may omit the error correction operation when the correction off signal ECC_OFF is activated, and may perform the error correction operation when the correction off signal ECC_OFF is deactivated.

Although not shown in FIG. 4, the ECC generation circuit 482 may be activated according to the write command WT during the write operation, and the error correction circuit 484 may be activated according to the read command RD during the read operation.

The mode setting circuit 492 may store data corresponding to the internal address ICA according to the mode setting command MRS. According to an embodiment, the internal address ICA may include a row address RADD. The mode setting circuit 492 may include a known mode register set.

Meanwhile, a per-DRAM addressability (PDA) mode may be supported so that an independent mode register setting operation may be performed for each of the memory devices that share a command/address bus, even though a data bus is separated. The memory device 101 may check a specific bit (e.g., a first bit CDATA<0>) of the data CDATA input after a predetermined time from an input of the mode setting command MRS. The memory device 101 may determine that the internal address ICA is valid when the specific bit is a low bit, and determine that the internal address ICA is invalid when the specific bit of the input data CDATA is a high bit.

That is, the mode setting circuit 492 may determine an entry to the PDA mode according to the mode setting command MRS, to store a preliminary off mode signal OFF_FLAG and an off address OFF_ADD included in the internal address ICA during the PDA mode. The mode setting circuit 492 may transmit the preliminary off mode signal OFF_FLAG and the off address OFF_ADD stored therein to the error correction control circuit 494, according to the mode setting command MRS. The off address OFF_ADD may include an off-start address S_ADD designating a start point of the exclusion area and an off-end address E_ADD designating an end point of the exclusion area.

The error correction control circuit 494 may generate the correction off signal ECC_OFF by checking whether a target area, in which data are to be read, is included in an exclusion area defined by the off address OFF_ADD, according to the preliminary off mode signal OFF_FLAG or the off command EOFF. The error correction control circuit 494 may define the exclusion area by the off-start address S_ADD and the off-end address E_ADD, which are included in the off address OFF_ADD. The error correction control circuit 494 may activate the correction off signal ECC_OFF when the target area is included in the exclusion area. The error correction control circuit 494 may receive the read command RD indicating the read operation and the row address RADD defining the target area.

According to an embodiment, the memory device 101 may further include an output circuit 496 driven according to the correction off signal ECC_OFF. The output circuit 496 may be activated according to the correction off signal ECC_OFF, and output the error correction code ECC read from the target area to the memory controller 200 through a separate pad SP_P, during the read operation. According to an embodiment, the output circuit 496 may output the error correction code ECC as a separate signal PAR.

FIG. 5 is a diagram illustrating an exclusion area defined by an off address of FIG. 4 according to an embodiment of the present disclosure.

Referring to FIG. 5, an exclusion area OFF_R of the memory cell region 410 is illustrated. Assuming that first to 4096-th word lines WL<0> to WL<4095> are disposed in the memory cell region 410, an off-start address S_ADD corresponding to a row address designating a k-th word line WL<k−1> and an off-end address E_ADD corresponding to a row address designating a (k+3)-th word line WL<k+2> may define the exclusion area OFF_R including k-th to (k+3)-th word lines WL<k−1> to WL<k+2>. In an embodiment of FIG. 5, the exclusion area OFF_R is defined by the off address OFF_ADD corresponding to the row address, but the proposed invention is not limited thereto. According to an embodiment, the exclusion area OFF_R may be defined by the off address OFF_ADD corresponding to both the row address and the column address.

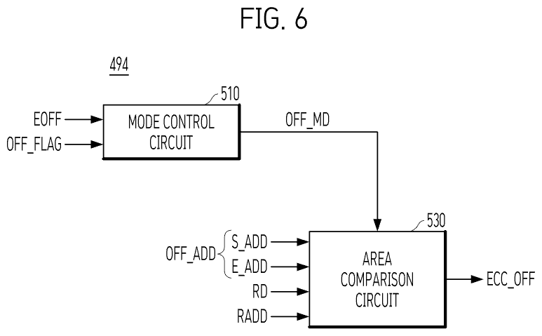

FIG. 6 is a detailed block diagram illustrating an error correction control circuit of FIG. 4 according to an embodiment of the present disclosure.

Referring to FIG. 6, an error correction control circuit 494 may include a mode control circuit 510 and an area comparison circuit 530.

The mode control circuit 510 may generate an off mode signal OFF_MD according to the preliminary off mode signal OFF_FLAG or the off command EOFF. The mode control circuit 510 may activate the off mode signal OFF_MD when any one of the preliminary off mode signal OFF_FLAG and the off command EOFF is activated. The mode control circuit 510 may perform a logic OR operation on the preliminary off mode signal OFF_FLAG and the off command EOFF.

The area comparison circuit 530 may generate the correction off signal ECC_OFF by comparing the row address RADD, the off-start address S_ADD, and the off-end address E_ADD according to the off mode signal OFF_MD, during the read operation determined by the read command RD. The area comparison circuit 530 may activate the correction off signal ECC_OFF when the row address RADD is included between the off-start address S_ADD and the off-end address E_ADD.

Hereinafter, an operation of a memory device according to an embodiment of the present invention will be described with reference to FIGS. 4 to 8.

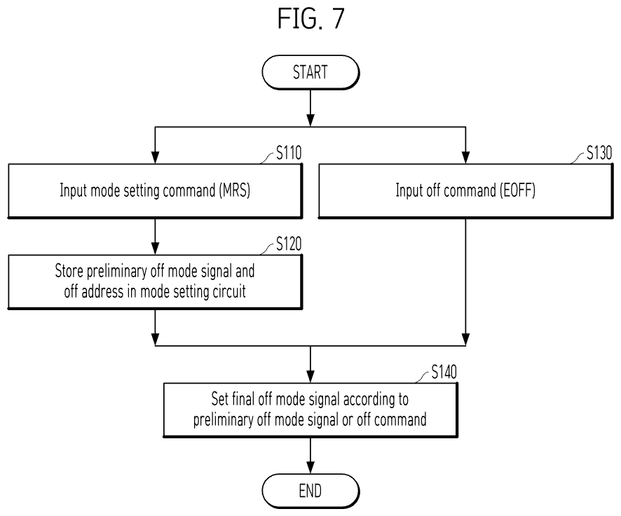

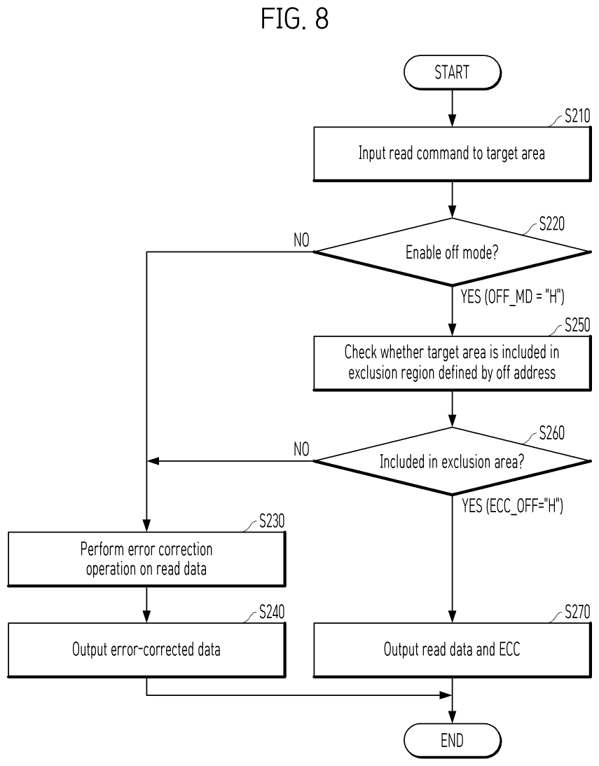

FIGS. 7 and 8 are flowcharts for describing an operation of a memory device according to an embodiment of the present disclosure.

Referring to FIG. 7, a memory device 101 may receive a mode setting command MRS from a memory controller 200 (at S110). The memory device 101 may receive an internal address ICA together with the mode setting command MRS as a command/address signal C/A.

The mode setting circuit 492 may store a preliminary off mode signal OFF_FLAG and an off address OFF_ADD according to the mode setting command MRS (at S120). The mode setting circuit 492 may determine an entry to a PDA mode according to the mode setting command MRS, to store the preliminary off mode signal OFF_FLAG and the off address OFF_ADD according to the row address RADD included in the internal address ICA in the PDA mode. In this case, even if the off address OFF_ADD is valid, the preliminary off mode signal OFF_FLAG may have a deactivated state.

The memory controller 200 may additionally provide an off command EOFF at a desired time point (i.e., on the fly) between operations of each of the memory devices 101 to 110 (at S130).

The error correction control circuit 494 may generate an off mode signal OFF_MD according to the preliminary off mode signal OFF_FLAG or the off command EOFF (at S140). The error correction control circuit 494 may activate the off mode signal OFF_MD when one of the preliminary off mode signal OFF_FLAG and the off command EOFF is activated. That is, the off mode signal OFF_MD may be activated by the off command EOFF even when the off mode signal is not set by the mode setting command MRS.

Referring to FIG. 8, the memory device 101 may receive a read command RD for a target area of the memory cell region 410 from the memory controller 200 (at S210). Accordingly, a read operation may be performed on the target area.

When the off mode signal OFF_MD is deactivated (“NO” in S220), the error correction control circuit 494 may deactivate the correction off signal ECC_OFF, and accordingly, the error correction circuit 484 may perform an error correction operation of correcting an error of data IDATA read from the target area using an error correction code ECC read from the target area (at S230), and output error-corrected data CDATA (at S240).

On the other hand, when the off mode signal OFF_MD is activated (“YES” in S220), the error correction control circuit 494 may check whether the target area is included in an exclusion area defined by the off address OFF_ADD (at S250). The error correction control circuit 494 may compare the row address RADD provided with the read command RD with the off-start address S_ADD and the off-end address E_ADD, respectively, and determine that the target area is included in the exclusion area when the row address RADD is included between the off-start address S_ADD and the off-end address E_ADD (at S260).

When the target area is not included in the exclusion area (“NO” in S260), the error correction control circuit 494 may deactivate the correction off signal ECC_OFF, and accordingly, the error correction circuit 484 may correct the error of the data IDATA read from the target area using the error correction code ECC read from the target area (at S230), and output the error-corrected data CDATA (at S240).

On the other hand, when the target area is included in the exclusion area (“YES” in S260), the error correction control circuit 494 may activate the correction off signal ECC_OFF, and accordingly, the error correction circuit 484 may omit the error correction operation, and the data output circuit 454 may output the data IDATA read from the target area to the memory controller 200 through the data pad DQ_P without a change, i.e., without correcting an error of the data IDATA (at S270). Depending on an embodiment, the output circuit 496 may be activated according to the correction off signal ECC_OFF, to output the error correction code ECC read from the target area to the memory controller 200 through the separate pad SP_P.

Hereinafter, an operation of the memory system 10 according to an embodiment of the present invention will be described with reference to FIGS. 1 to 10C.

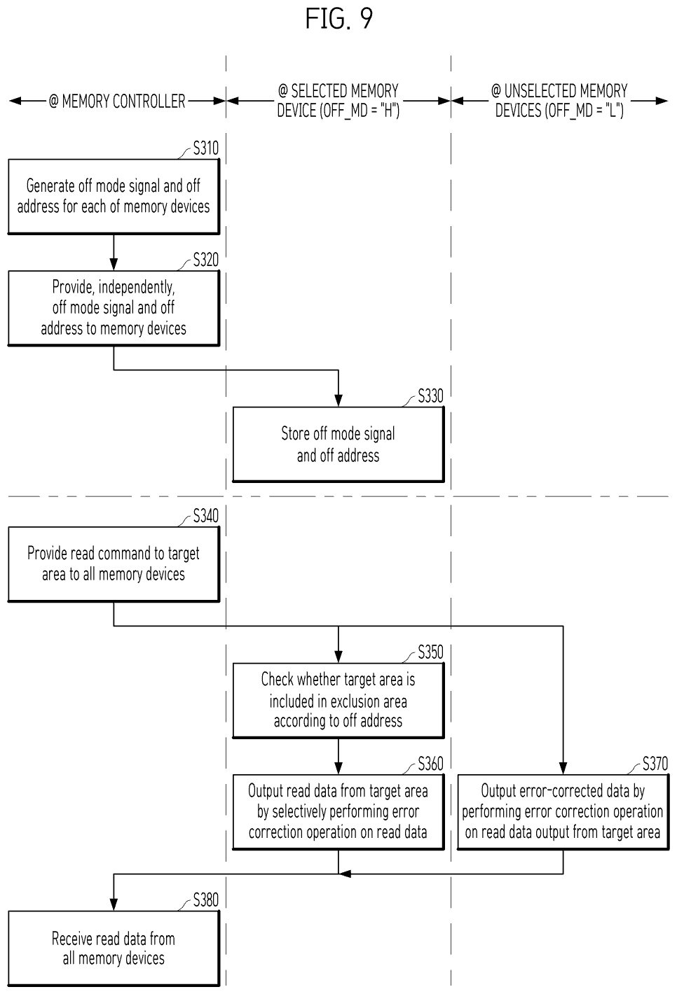

FIG. 9 is a flowchart for explaining an operation of a memory system according to an embodiment of the present disclosure.

Referring to FIG. 9, a memory controller 200 may collect an address of an area where an error (i.e., a multi-bit error) beyond the error correction capability has occurred in each of the memory devices 101 to 110 based on the data DIO during a read operation. The memory controller 200 may generate an off mode signal OFF_MD and an off address OFF_ADD for each of the memory devices 101 to 110 based on the collected addresses (at S310).

The memory controller 200 may independently provide the off mode signal OFF_MD and the off address OFF_ADD to each of the plurality of memory devices 101 to 110 (at S320). The off mode signal OFF_MD and the off address OFF_ADD may be provided in the form of a command/address signal C/A. Each of the memory devices 101 to 110 may store the off mode signal OFF_MD and the off address OFF_ADD corresponding thereto (at S330).

Depending on an embodiment, the memory controller 200 may independently provide an off mode signal OFF_MD and an off address OFF_ADD to each of the memory devices 101 to 110 together with a mode setting command MRS. Each of the memory devices 101 to 110 may enter a PDA mode according to the mode setting command MRS to store the off mode signal OFF_MD and the off address OFF_ADD.

Depending on an embodiment, the memory controller 200 may independently provide an off address OFF_ADD together with a mode setting command MRS to each of the memory devices 101 to 110, and may additionally provide an off command OFF at a desired time point between operations of each of the memory devices 101 to 110. Each of the memory devices 101 to 110 may enter a PDA mode according to the mode setting command MRS to store the off address OFF_ADD, and may activate an off mode signal OFF_MD according to the off command EOFF.

Thereafter, the memory controller 200 may provide a read command RD for a target area of the memory cell region 410, to all of the memory devices 101 to 110 (at S340).

A selected memory device in which the off mode signal OFF_MD is activated, from among the memory devices 101 to 110, may check whether the target area is included in an exclusion area defined by the off address OFF_ADD (at S350). The selected memory device may compare a row address RADD provided with the read command RD with an off-start address S_ADD and an off-end address E_ADD, respectively. When the row address RADD is included between the off-start address S_ADD and the off-end address E_ADD, the selected memory device may determine that the target area is included in the exclusion area.

The selected memory device may output data IDATA read from the target area by selectively performing an error correction operation on the data IDATA according to the check result (at S360). According to the check result, when the target area is not included in the exclusion area, the selected memory device may correct an error of the data IDATA read from the target area using the error correction code ECC read from the target area, to output error-corrected data CDATA. On the other hand, according to the check result, when the target area is included in the exclusion area, the selected memory device may omit the error correction operation to output the data IDATA read from the target area as is, without correction. In this case, the selected memory device may output the error correction code ECC read from the target area to the memory controller 200 through a separate pad SP_P.

The remaining unselected memory devices in which the off mode signal OFF_MD is deactivated, from among the memory devices 101 to 110, may correct an error of the data IDATA read from the target area using the error correction code ECC read from the target area, and output the error-corrected data CDATA to the memory controller 200 (at S370).

Thereafter, the memory controller 200 may receive both the uncorrected read data transmitted from the selected memory device in which the off mode signal OFF_MD is activated, and the error-corrected data transmitted from the unselected memory devices in which the off mode signal OFF_MD is deactivated (at S380). As a result, by correcting a multi-bit error of read data provided from all memory devices 101 to 110, the memory controller 200 may prevent the occurrence of an uncorrectable error (UE) due to the miscorrection of the on-chip ECC engine of the memory device, and manage errors to fall within the fault boundary coverage.

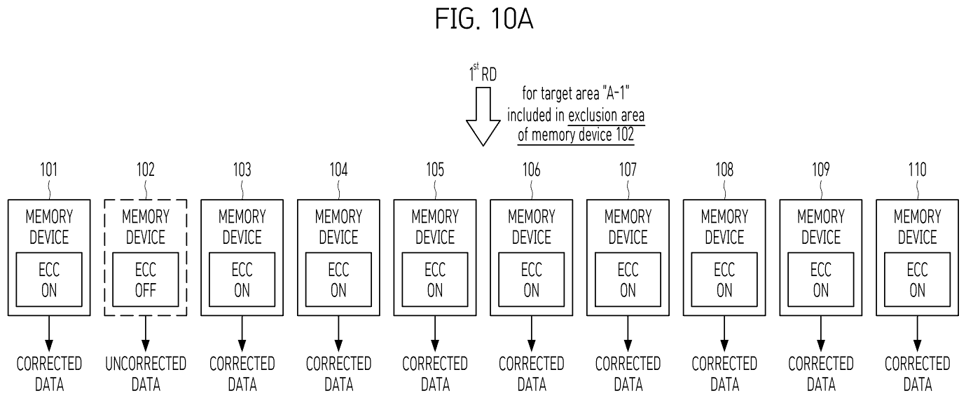

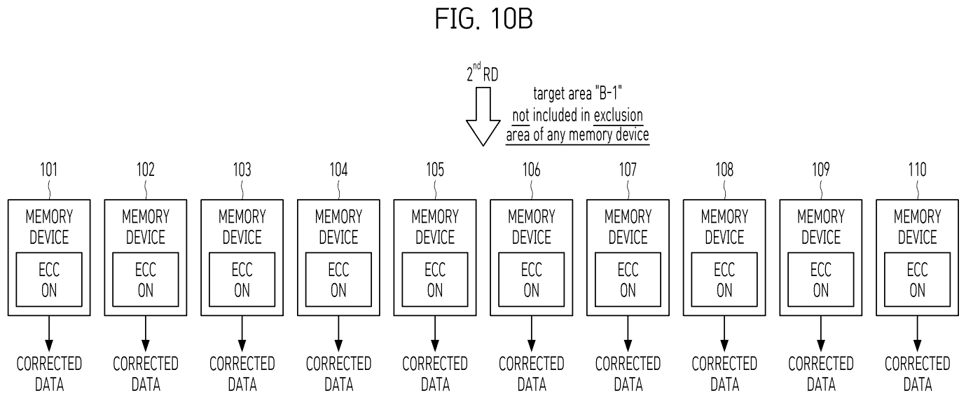

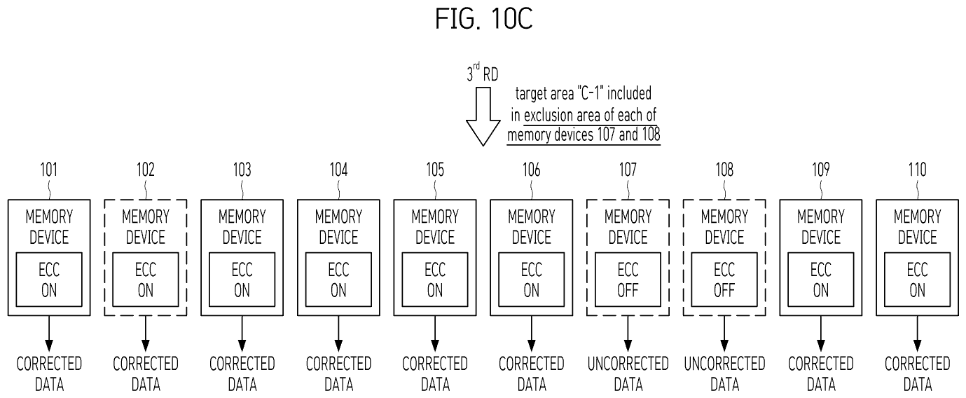

FIGS. 10A to 10C are diagrams illustrating operations of a memory system according to an embodiment of the present disclosure.

Hereinafter, it is assumed that an off mode signal OFF_MD of memory devices 102, 107 and 108 from among a plurality of memory devices 101 to 110 is activated, an off-address OFF_ADD for the exclusive area “A” is stored in the memory device 102, and an off-address OFF_ADD for an exclusive area “C” is stored in the memory devices 107 and 108, respectively.

Referring to FIG. 10A, the memory devices 101 to 110 may receive a first read command RD indicating a read operation for a target area “A-1” from a memory controller 200. The memory device 102 may confirm that the target area “A-1” is included in the exclusion area “A”, and output data IDATA in which an error read from the target area has not been corrected. That is, only the memory device 102 may output uncorrected data. The remaining memory devices 101 and 103 to 110 may output error-corrected data CDATA by correcting an error of data IDATA read from the target area by using the error correction code ECC read from the target area.

Referring to FIG. 10B, the memory devices 101 to 110 may receive a second read command RD indicating a read operation for a target area “B-1” from the memory controller 200. All memory devices 101 to 110 may confirm that the target area “B-1” is not included in any exclusion area, and may output error-corrected data CDATA by correcting an error of the data IDATA read from the target area using the error correction code ECC read from the target area.

Referring to FIG. 10C, the memory devices 101 to 110 may receive a third read command RD indicating a read operation for a target area “C-1” from the memory controller 200. Each of the memory devices 107 and 108 may confirm that the target area “C-1” is included in the exclusion area “C”, and output data IDATA in which an error read from the target area is not corrected. That is, the memory devices 107 and 108 may output uncorrected data. The remaining memory devices 101 to 106 and 109 to 110 may output error-corrected data CDATA by correcting an error of the data IDATA read from the target area using the error correction code ECC read from the target area.

Various embodiments of the present disclosure have been described in the drawings and specification. Although specific terminologies are used here, the terminologies are only to describe the embodiments of the present disclosure. Therefore, the present disclosure is not restricted to the above-described embodiments and many variations are possible within the spirit and scope of the present disclosure. It should be apparent to those skilled in the art that various modifications can be made based on the technological scope of the present disclosure in addition to the embodiments disclosed herein. The embodiments may be combined to form additional embodiments.

It should be noted that although the technical spirit of the disclosure has been described in connection with embodiments thereof, this is merely for description purposes and should not be interpreted as limiting. It should be appreciated by one of ordinary skill in the art that various changes may be made thereto without departing from the technical spirit of the present disclosure and the following claims.

What is claimed is:

1. A memory system, comprising:
a plurality of memory devices each including a memory cell region and an error correction circuit; and
a memory controller configured to independently provide an off mode signal and an off address to the plurality of memory devices,
wherein, during a read operation, each of the plurality of memory devices controls the error correction circuit to selectively perform an error correction operation on an exclusion area in the memory cell region defined by the off address, according to the off mode signal.

2. The memory system of claim 1, wherein the memory controller independently provides the off mode signal and the off address to the plurality of memory devices along with a mode setting command.

3. The memory system of claim 1,
wherein the memory controller independently provides the off address to the plurality of memory devices along with a mode setting command, and
wherein the memory controller further provides an off command for setting the off mode signal to each of the plurality of memory devices.

4. The memory system of claim 1,
wherein each of the plurality of memory devices defines the exclusion area according to the off address,
wherein each of the plurality of memory devices omits the error correction operation on data when a target area with the data is included in the exclusion area, and performs the error correction operation on data when the target area with the data is not included in the exclusion area.

5. The memory system of claim 1, wherein, for each of the plurality of memory devices, the memory controller collects an address of an area where an error has occurred beyond an error correction capability, and generates the off mode signal and the off address for each of the plurality of memory devices based on the collected addresses.

6. A memory device, comprising:
a memory cell region;
an error correction circuit configured to selectively perform an error correction operation on data read from a target area in the memory cell region according to a correction off signal, during a read operation;
a mode setting circuit configured to store a preliminary off mode signal and an off address according to a mode setting command; and
an error correction control circuit configured to generate the correction off signal by checking whether the target area is included in an exclusion area defined by the off address according to an off command or the preliminary off mode signal.

7. The memory device of claim 6, wherein the mode setting command and the off command are provided from a memory controller.

8. The memory device of claim 6, wherein the error correction control circuit includes:
a mode control circuit configured to generate an off mode signal according to the off command or the preliminary off mode signal; and
an area comparison circuit configured to activate the correction off signal when a row address input during the read operation is included between a start address and an end address, which are included in the off address, according to the off mode signal.

9. The memory device of claim 6, further comprising:
an output circuit configured to output an error correction code read from the target area through a separate pad according to the correction off signal, during the read operation.

10. The memory device of claim 6, further comprising:
an error correction code generation circuit configured to generate an error correction code using write data during a write operation,
wherein the memory cell region stores the write data and the error correction code.

11. An operating method of a memory device, comprising:
storing a preliminary off mode signal and an off address in a mode setting circuit according to a mode setting command;
generating an off mode signal according to an off command or the stored preliminary off mode signal;
receiving a read command for a target area in a memory cell region;
checking whether the target area is included in an exclusion area defined by the off address according to the off mode signal; and
selectively performing an error correction operation on data read from the target area according to the checking result.

12. The operating method of claim 11, wherein the checking whether the target area is included in the exclusion area includes:
comparing a row address designating the target area with a start address and an end address, which are included in the off address; and
determining that the target area is included in the exclusion area when the row address is included between the start address and the end address.

13. The operating method of claim 11, wherein the selectively performing the error correction operation includes:
omitting the error correction operation on the data read from the target area when the target area is included in the exclusion area.

14. The operating method of claim 11, further comprising:
outputting the read data on which the error correction operation is omitted through a data pad, and outputting an error correction code read from the target area through a separate pad.

15. The operating method of claim 11, further comprising:
providing the mode setting command and the off command from a memory controller.

16. An operating method of a memory system, comprising:
providing, at a memory controller, an off mode signal and an off address defining an exclusion area to at least one selected memory device among a plurality of memory devices;
storing the off mode signal and the off address, at the selected memory device;
providing, at the memory controller, a read command for a target area to the plurality of memory devices;
checking, at the selected memory device, whether the target area is included in the exclusion area according to the off mode signal and the off address; and
selectively performing, at the selected memory device, an error correction operation on data read from the target area according to the checking result.

17. The operating method of claim 16, wherein the memory controller provides the off mode signal and the off address to the selected memory device, along with a mode setting command.

18. The operating method of claim 16,
wherein the memory controller provides the off address to the selected memory device along with a mode setting command, and
wherein the memory controller further provides an off command for setting the off mode signal to the selected memory device.

19. The operating method of claim 16, wherein the checking whether the target area is included in the exclusion area includes:
defining the exclusion area according to the off address;
comparing a row address designating the target area with a start address and an end address, which are included in the off address; and
determining that the target area is included in the exclusion area when the row address is included between the start address and the end address.

20. The operating method of claim 16, further comprising:
omitting the error correction operation on the read data at the selected memory device, while performing an error correction operation on the read data at each of unselected memory devices, when the target area is included in the exclusion area.

21. The operating method of claim 16, further comprising:
collecting, at the memory controller, an address of an area where an error has occurred beyond an error correction capability of each of the plurality of memory devices, and generating the off mode signal and the off address for each of the plurality of memory devices based on collected addresses.
